(19) United States
(12) Patent Application Publication
(10) Pub. No.: US 2024/0111217 A1
(43) Pub. Date: Apr. 4, 2024

(54) METHOD FOR DIRECTED SELF-ASSEMBLY LITHOGRAPHY

(71) Applicants: ARKEMA FRANCE, Colombes (FR); CENTRE NATIONAL DE LA RECHERCHE SCIENTIFIQUE, Paris (FR); UNIVERSITE DE BORDEAUX, Bordeaux (FR); INSTITUT POLYTECHNIQUE DE BORDEAUX, Talence (FR); UNIVERSITE GRENOBLE ALPES, Saint Martin D'Heres (FR)

(72) Inventors: Xavier Chevalier, Grenoble (FR); Matthieu Sérégé, Toulouse (FR); Cindy Gomes Correia, Noisy-le-sec (FR); Marc Zelsmann, Biviers (FR); Guillaume Fleury, Talence (FR)

(21) Appl. No.: 17/768,522

(22) PCT Filed: Oct. 15, 2020
(86) PCT No.: PCT/FR2020/051847

§ 371 Date: Apr. 13, 2022

(30) Foreign Application Priority Data
Oct. 16, 2019 (FR) FR1911521

(51) Int. Cl. G03F 7/00

(52) U.S. Cl. CPC G03F 7/70383; G03F 7/0002; H01L 21/0271

(57) ABSTRACT

The invention relates to a method of directional self-assembly lithography, said method comprising a step of depositing a block copolymer film on a layer (20) neutral with respect the block copolymer, said block copolymer film being for use as a lithography mask, said method being characterized in that it comprises the following steps of:
depositing said neutral layer (20) on a surface of a substrate (10), said neutral layer (20) being of the carbon or fluoro-carbon type deposited to a thickness greater than 1.5 times the thickness of the block copolymer film (40),
crosslinking said neutral layer,
depositing said block copolymer film, comprising at least one silylated block, on said crosslinked neutral layer (30),
subjecting the stack to an assembly temperature in order to nanostructure said block copolymer,
removing (G1) at least one of the nano-domains (41, 42) from the nanostructured block copolymer film (40), in order to create a pattern intended to be transferred by etching (G2, G3, G4) into the thickness of the substrate (10).

The invention is concerned with the field of microelectronics and organic electronics, and more particularly with directed self-assembly nanolithography applications, also known as DSA (from the English acronym “Directed Self-Assembly”).

The invention relates more particularly to a directed self-assembly lithography method, said method comprising a block copolymer film as a lithography mask for the creation of several patterns.

### PRIOR ART

Since the 1960s, block copolymers have been a very broad field of research for the development of new materials. It is possible to modulate and control their properties by the chemical nature of the blocks and their architecture for the intended application. For specific macromolecular parameters (Mₙ, Iₚ, f, χ, N), block copolymers are capable of self-assembling and forming structures, the characteristic dimensions (10-100 nm) of which constitute today a major challenge in the field of microelectronics and microelectromechanical systems (MEMS).

Typically, in microelectronics for example, a lithography method is implemented in order to be able to etch a substrate through a lithography mask and create a recessed pattern for making an electronic circuit. To be able to perform such lithography, a stack of layers of materials with predetermined properties is required, in order to transfer the pattern very selectively through the different layers, usually by plasma etching with distinct gas chemistries, and to obtain a pattern in the substrate with an important final form factor, typically with a height/width H/W ratio greater than or equal to 1.

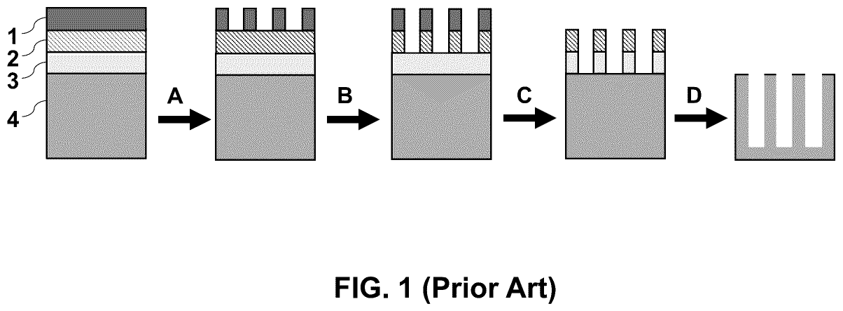

Generally, in lithography, the standard stack comprises, as shown in FIG. 1, a lithography resin 1, a silylated resin layer 2, that is to say filled with silicon and having optical anti-reflection properties of a given wavelength (for example at a wavelength of 193 nm, if the lithographic resin is exposed at 193 nm), particularly a SiARC (English acronym for “Silicon Anti-Reflective Coating”) or SOG (English acronym for “Spin-on-Glass”) layer, a thicker SOC (English acronym for “Spin On Carbon”) carbon layer 3, and a substrate 4.

In quite a classical way, the lithography resin is first structured A, by drawing the pattern of interest on it by any method such as UV photolithography (irradiation at 193 nm for a common source with advanced resolutions), and then this pattern is transferred B into the underlying SiARC/SOG layer via fluorinated plasma chemistry (such as CF₄, SF₆, etc.). This silylated pattern is then itself transferred C into the thick layer of carbon resin SOC via oxygen-based (or other than fluorinated) chemistry, and then this latter pattern is transferred D into the substrate by plasma etching with fluorinated gas chemistry.

Thus, successive stacks of materials with particular atomic constitution allow the pattern to be transferred very selectively in the different layers by plasma etching with very distinct gas chemistries, allowing a substrate to be deeply etched.

In the particular context of applications in the field of directed self-assembly nanolithography, or DSA (English acronym for “Directed Self-Assembly”), block copolymers, which are capable of nanostructuring at an assembly temperature, are used as nanolithography masks. Block copolymers, once nanostructured, allow patterns to be obtained, for creating nanolithography masks, with a periodicity of less than 20 nm, which is difficult to achieve with conventional lithography techniques. In addition, the production of a self-assembled block copolymer with a periodicity of less than 10 nm is made possible by the use of block copolymers, the blocks of which have a high incompatibility, that is to say with a high Flory-Huggins interaction parameter, χ. This high parameter results in a difference in the physico-chemical properties between the blocks and in particular in the surface energy. In the case of the lamellar phase in particular, this large difference in surface energy favors the orientation of the domains parallel to the substrate surface. However, in order to serve as a nanolithography mask, such a block copolymer must have nanodomains oriented perpendicularly to the lower and upper interfaces of the block copolymer, so as to be able to then selectively remove one of the nanodomains of the block copolymer, create a porous film with the residual nanodomain(s), and transfer, by etching, the thus created patterns to the underlying substrate. However, this condition of perpendicularity of the patterns is fulfilled only if each of the lower (substrate/block copolymer) and upper (block copolymer/ambient atmosphere) interfaces is “neutral” with respect to each of the blocks of said block copolymer, subsequently denoted BCP, that is to say there is no preponderant affinity of the interface under consideration for at least one of the blocks constituting the block copolymer BCP.

In these conditions, the standard stacking, in the context of DSA lithography, to create a pattern to a significant depth, said pattern having a depth typically greater than 20 nm, in the thickness of a substrate, said thickness of the substrate being typically of the order of a hundred micrometers, or even several hundred micrometers, with an important form factor, typically greater than 1, without causing it to collapse, comprises at least: a block copolymer, an underlayer neutral with respect to each of the blocks of the block copolymer, a SiARC or SOG layer, an SOC layer, and the substrate. Si-ARC/SOG layers are important in microelectronic lithography methods because they allow patterns to be transferred into the substrate with large form factors and at depths not otherwise accessible. SiARC is a material with a composition close to a silicon-rich oxide. In this case, this gives it anti-reflective optical properties that limit multiple reflections of the light beams at its interface with the BCP, thus minimizing the appearance of afterimages that impact in particular the roughness of the final patterns.

All these stacked layers (BCP, neutral layer, Si-ARC/SOG, SOC) are used to deeply etch a substrate, but require a high consumption of resources. Indeed, the number of steps is important, the materials used are numerous, which impacts the cost and time of production, all of which leads to high production costs.

In addition, the use of block copolymers requires perfect control of the interfaces to allow the patterns to be oriented perpendicular to the interfaces, in order to transfer them into the substrate. Such stacking represents a significant cost in resources and time for the chip manufacturer, especially when yields require a large volume (150 to 200 wafers per hour). Consequently, a reduction in the volume of these layers and the associated steps (dispensing by spin-coating, thermal annealing, rinsing, etc.) appears necessary to optimize yields.

It therefore appears necessary to optimize the stacks that can be used in DSA in order to maximize production yields, without impacting the final properties of the stack, while favoring an optimum form factor.

Thus, for particular applications, it can be interesting to be able to etch thick substrates, of the order of several hundred micrometers, at great depths typically greater than or equal to 20 nm. There is therefore a need to limit the number of layers in the stack used as well as the number of steps in the DSA lithography method, in order to limit costs and production time.

### TECHNICAL PROBLEM

The invention therefore aims to overcome the disadvantages of the prior art. In particular, the invention aims at proposing a directed self-assembly lithography method, said method being fast and simple to implement, with a reduced number of steps, and allowing production costs to be controlled. The method must also allow patterns to be transferred into substrates at great depths without these patterns collapsing and becoming unusable.

### BRIEF DESCRIPTION OF THE INVENTION

To this end, the invention relates to a directed self-assembly lithography method, said method comprising a step of depositing a block copolymer film on a layer neutral with respect to each of the blocks of the block copolymer, said block copolymer film being for use as a lithography mask, said lithography method being characterized in that it comprises the following steps of:
depositing said neutral layer directly on a surface of a substrate, said neutral layer being of the carbon or fluoro-carbon type (n-SOC) deposited to a thickness greater than 1.5 times the thickness of the block copolymer film,
crosslinking all or part of said carbon or fluoro-carbon neutral layer,
depositing said block copolymer film on said crosslinked carbon or fluoro-carbon neutral layer, said block copolymer comprising at least one silylated block,
subjecting the stack of layers thus created to an assembly temperature in order to nanostructure said block copolymer,
removing at least one of the nano-domains from said nanostructured block copolymer film, in order to create a pattern intended to be transferred by etching into the carbon or fluoro-carbon neutral layer, and then into the thickness of the underlying substrate.

According to other optional features of the method:
the carbon or fluoro-carbon neutral layer comprises reactive groups of the epoxy type and/or unsaturations in its polymer chain, either directly in the body of the polymer chain itself, or as a pendant group therein;
the minimum rate of reactive groups of the epoxy type and/or of unsaturations in the polymer chain of the carbon or fluoro-carbon neutral layer is between 5% and 90%, preferably between 10% and 70%, and more preferably between 20% and 35% by weight;
the carbon or fluoro-carbon neutral layer further comprises a latent crosslinking agent selected from derivatives of the organic peroxide type, or derivatives having a chemical function of the azo type such as azobisisobutyronitrile, or derivatives of the alkyl halide type, or chemical derivatives for generating a thermally activated acid proton, such as ammonium salts such as ammonium triflate, ammonium trifluoroacetate, or ammonium trifluoromethane sulfonate, pyridinium salts such as pyridinium para-toluenesulfonate, phosphoric or sulfuric or sulfonic acids, or onium salts such as iodonium or phosphonium salts, or imidazolium salts, or photo-generated acids or photo-generated bases;
the carbon or fluoro-carbon neutral layer has, in whole or in part, a chemical structure of the acrylate or methacrylate type based on comonomers selected from (meth)acrylic monomers such as hydroxyalkyl acrylates such as 2-hydroxyethyl acrylate, glycidyl acrylates, dicyclopentenyloxyethyl acrylates, fluorinated methacrylates such as 2,2,2-trifluoroethyl methacrylate, tert-butyl acrylate or methacrylate, alone or as a mixture of at least two of the aforementioned comonomers;
the carbon or fluoro-carbon neutral layer comprises hydroxy groups promoting its solubility in polar solvents selected from at least one of the following solvents, taken alone or as a mixture: MIBK, methanol, isopropanol, PGME, ethanol, PGMEA, ethyl lactate, cyclohexanone, cyclopentanone, anisole, alkyl acetate, n-butyl acetate, iso-amyl acetate;
the carbon or fluoro-carbon neutral layer comprises at least three co-monomers of the glycidyl (meth)acrylate type (G), the hydroxyalkyl (meth)acrylate (H) type, and the fluoroalkyl (meth)acrylate (F) type, and the proportion of each monomer G, H, F is between 10 and 90% by weight, with the sum of the 3 monomers being equal to 100%;
it may comprise a step of depositing a third layer on a surface of the block copolymer, and prior to the step of nano-structuring the block copolymer, this third layer is crosslinked in whole or in part;
the step of crosslinking the carbon or fluoro-carbon neutral layer and/or the third layer is carried out by light irradiation, exposure to self-thermalization, electrochemical process, plasma, ion bombardment, electron beam, mechanical stress, exposure to a chemical species, or any combination of the aforementioned techniques;
the step of crosslinking the carbon or fluoro-carbon neutral layer is carried out by exposure to thermalization, at a temperature between 0° C. and 450° C., preferably between 100° C. and 300° C., and more preferably between 200 and 250° C. for a period of less than or equal to 15 minutes, preferably less than or equal to 2 minutes;
a pattern can be drawn in the third layer and/or in the underlayer, by exposure to light radiation or an electron beam or by any method known to the one skilled in the art;
when the pattern is drawn by exposure to light radiation, at least the carbon or fluoro-carbon neutral underlayer and the block copolymer have anti-reflection properties;
when the pattern is drawn by exposure to light radiation, a bottom anti-reflection coating (BARC) is dispensed on the substrate, prior to the deposition of said carbon or fluoro-carbon neutral underlayer;
the carbon or fluoro-carbon neutral underlayer may have a chemical structure identical to that of said third layer;
the third layer comprises a latent crosslinking agent selected from: chemical derivatives for generating a thermally activated acid proton, such as ammonium salts such as ammonium triflate, ammonium trifluoroacetate, or ammonium trifluoromethane sulfonate, or onium salts such as iodonium or sulfonium salts, such as triphenylsulfonium triflate, or phosphonium or imidazolium salts, or a photo-generated acid (PAG) or a photo-generated base (PBG).

In another aspect the invention relates to a lithography stack obtained by a directed self-assembly lithography method, said stack comprising a substrate to the surface of which is deposited a neutral layer, said neutral layer being covered by a block copolymer film, said block copolymer film being for use as a lithography mask, and said neutral layer being neutral with respect to each of the blocks of the block copolymer,
wherein the neutral layer is in direct contact with the underlying substrate, and the neutral layer being of the carbon or fluoro-carbon type (n-SOC), reticulated in whole or in part, deposited to a thickness greater than 1.5 times the thickness of said block copolymer film, and
wherein block copolymer film comprising at least one silylated block, and being in direct contact with said reticulated neutral layer, and
wherein said block copolymer film having been nanostructured for example by treatment at an assembly temperature and being a discontinuous film, in order to create a pattern capable of being transferred by etching in the layer neutral carbon or fluoro-carbon then in the thickness of the underlying substrate.

Other advantages and features of the invention will appear upon reading the following description given by way of illustrative and non-limiting example, with reference to the appended figures:

FIG. 1 represents a diagram of a method according to the prior art.

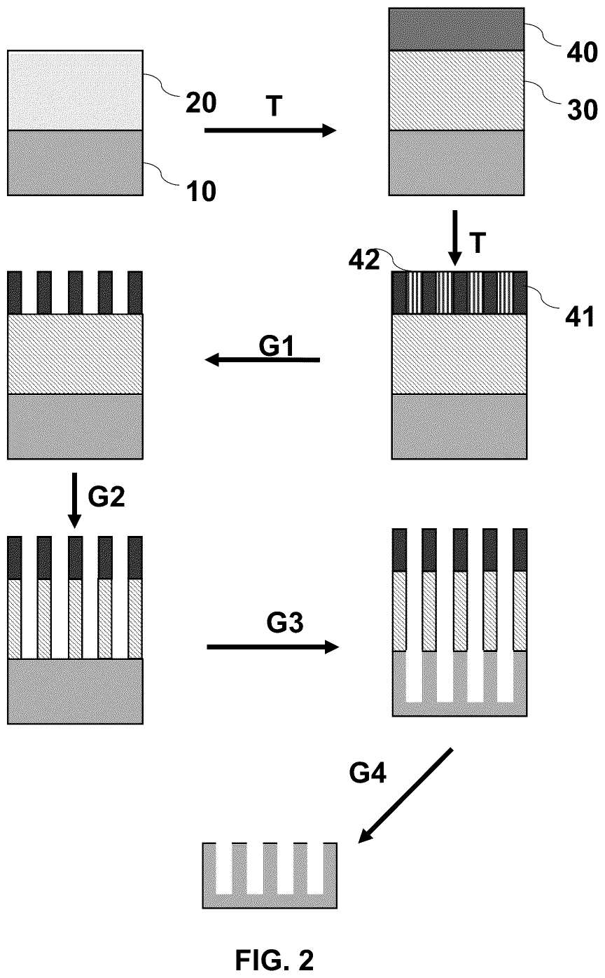

FIG. 2 represents a diagram of a method according to the invention.

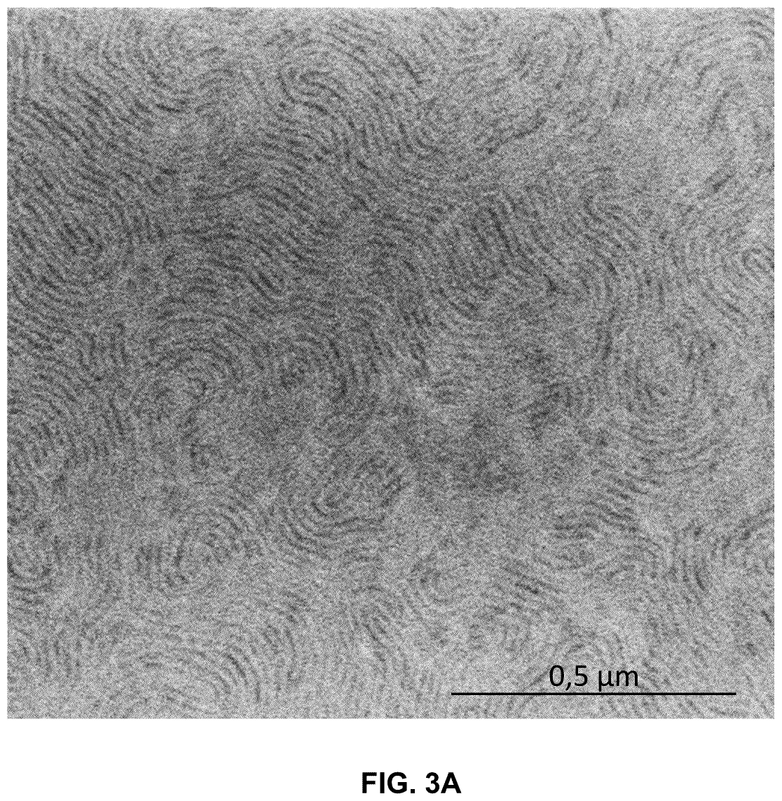

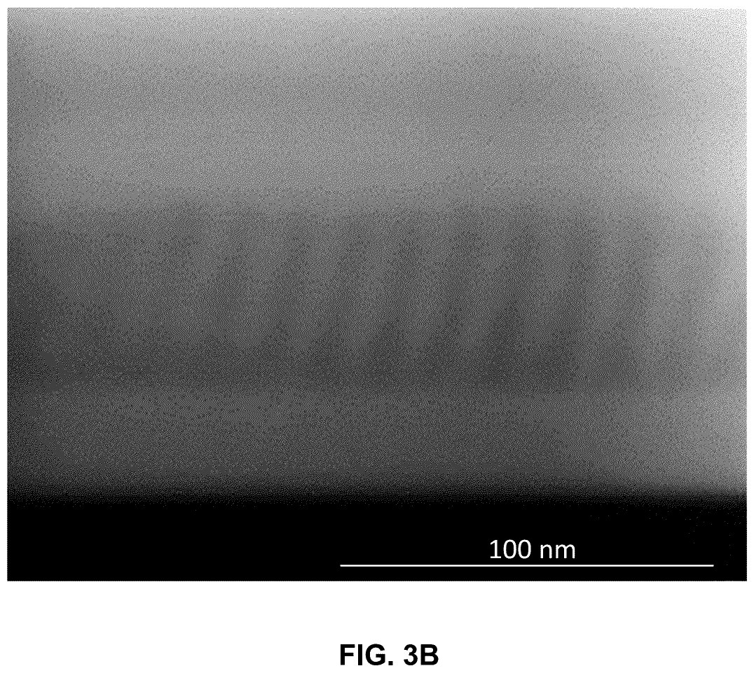

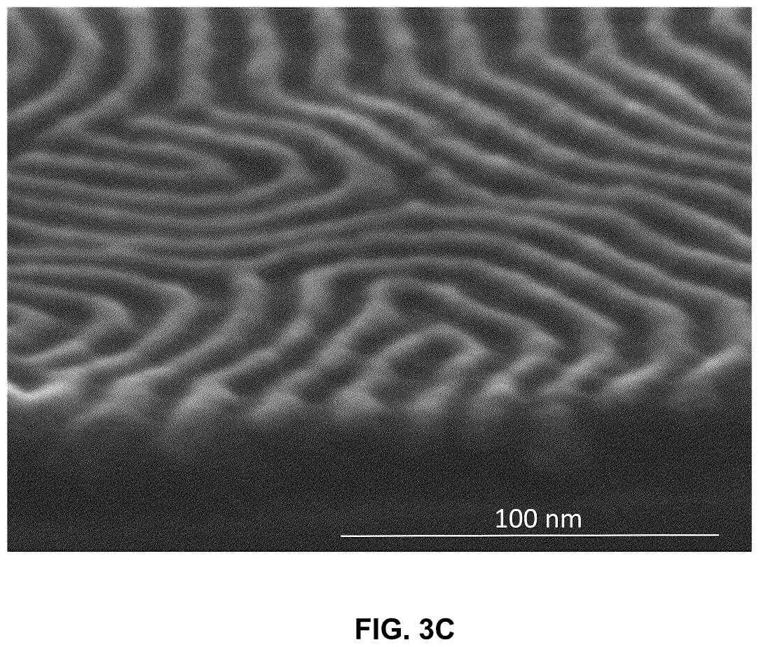

FIG. 3A FIG. 3B FIG. 3C represent top and cross-sectional photographs of a stack of layers used in the method according to the invention.

### DESCRIPTION OF THE INVENTION

In the following description, by “polymers” is meant either a copolymer (of the statistical, gradient, block, alternating type), or a homopolymer.

The term “monomer” as used refers to a molecule that can undergo polymerization.

The term “polymerization” as used refers to the method of transforming a monomer or a mixture of monomers into a polymer of a predefined architecture (block, gradient, statistical, etc.).

By “copolymer” is meant a polymer comprising several different monomer units.

By “statistical copolymer” is meant a copolymer in which the distribution of the monomer units along the chain follows a statistical law, for example of the Bernoullian (zero-order Markov) or first- or second-order Markovian type. When the repeating units are randomly distributed along the chain, the polymers were formed by a Bernoulli process and are called random copolymers. The term random copolymer is often used, even when the statistical process that prevailed during the synthesis of the copolymer is not known.

By “gradient copolymer” is meant a copolymer in which the distribution of the monomer units varies progressively along the chains.

By “alternating copolymer” is meant a copolymer comprising at least two monomer entities which are distributed alternately along the chains.

By “block copolymer” is meant a polymer comprising one or more uninterrupted sequences of each of the distinct polymer species, the polymer sequences being chemically different from each other and being linked together by a chemical bond (covalent, ionic, hydrogen bond, or coordinating bond). These polymer sequences are also referred to as polymer blocks. These blocks have a phase segregation parameter (Flory-Huggins interaction parameter) such that, if the degree of polymerization of each block is greater than a critical value, they are not miscible with each other and separate into nanodomains.

The above-mentioned term “miscibility” refers to the ability of two or more compounds to completely mix to form a homogeneous or “pseudo-homogeneous” phase, that is to say without apparent crystalline or near-crystalline symmetry over short or long distances. The miscibility of a mixture can be determined when the sum of the glass transition temperatures (Tg) of the mixture is strictly less than the sum of the Tg of the individual compounds taken alone.

In the description, “self-assembly”, “self-organization” or “nanostructuring” are equally used to describe the well-known phenomenon of phase separation of block copolymers, at an assembly temperature also called the annealing temperature.

The term “porous film” refers to a block copolymer film in which one or more nanodomains have been removed, leaving holes, the shapes of which correspond to the shapes of the nanodomains that have been removed and may be spherical, cylindrical, lamellar, or helical.

By “neutral” or “pseudo-neutral” surface is meant a surface which, as a whole, does not have preferential affinity with any of the blocks of a block copolymer. It thus allows an equitable or “pseudo-equitable” distribution of the blocks of the block copolymer on the surface. Neutralization of the surface of a substrate allows such a “neutral” or “pseudo-neutral” surface to be obtained.

By “non-neutral” surface is meant a surface which, as a whole, has a preferential affinity with one of the blocks of a block copolymer. It allows the nanodomains of the block copolymer to be oriented in a parallel or non-perpendicular manner.

The surface energy (denoted γx) of a given material “x” is defined as the excess energy at the surface of the material compared to that of the bulk material. When the material is in liquid form, its surface energy is equivalent to its surface tension.

When talking about surface energies or more precisely interfacial tensions of a material and a block of a given block copolymer, these are compared at a given temperature, and more precisely at a temperature allowing self-organization of the block copolymer.

By “lower interface” of a block copolymer is meant the interface in contact with an underlying layer or substrate on which said block copolymer is deposited. It should be noted that this lower interface is neutralized by a conventional technique, that is to say it does not, as a whole, have any preferential affinity with one of the blocks of the block copolymer.

By “upper interface” or “upper surface” of a block copolymer is meant the interface in contact with a top layer, called the top coat and denoted TC, applied to the surface of said block copolymer. It should be noted that the top layer of top coat TC, like the underlying layer, preferably has no preferential affinity to any of the blocks of the block copolymer so that the nanodomains of the block copolymer can orient perpendicularly to the interfaces during assembly annealing.

By “solvent orthogonal to a (co)polymer” is meant a solvent not likely to attack or dissolve said (co)polymer.

By “liquid polymer” or “viscous polymer” is meant a polymer which, at a temperature greater than the glass transition temperature, has, due to its rubbery state, an increased capacity for deformation as a result of the possibility given to its molecular chains to move freely. The hydrodynamic phenomena at the origin of dewetting appear as long as the material is not in a solid state, that is to say non-deformable due to the negligible mobility of its molecular chains.

By “discontinuous film” is meant a film, the thickness of which is not constant due to the shrinkage of one or more areas, leaving holes.

By “pattern” in a nanolithography mask is meant an area of a film comprising a succession of alternating recessed and protruding shapes, with said area having a desired geometric shape, and where the recessed and protruding shapes may be lamellae, cylinders, spheres, or gyroids.

By “unsaturation” in a polymeric chain is meant at least one “sp”- or “sp2”-hybridized carbon.

In a lithography method and particularly in DSA lithography, etching a pattern into a substrate at great depths without causing it to collapse is particularly poorly mastered or even not practiced.

In addition, lithography methods applied in DSA include a significant consumption of resources (number of layers, stacking, time, number of steps).

The applicant developed a DSA lithography method as shown in FIG. 2.

The self-assembly directed lithography method according to the invention uses a block copolymer film as a lithography mask.

The method according to the invention consists in depositing directly on the surface of a substrate 10, a layer 20, neutral with respect to each of the block copolymer blocks which will be deposited subsequently on said neutral layer. The neutral layer is a carbon or fluoro-carbon type layer (hereafter called n-SOC). The carbon or fluoro-carbon neutral layer is deposited to a thickness greater than 1.5 times the thickness of the block copolymer film.

The carbon or fluoro-carbon neutral layer, once deposited on the substrate, is crosslinked in whole or in part. The stack can then be optionally rinsed, for example with the same solvent as the one for depositing the neutral layer, in order to remove possible undesirable areas of the film. The block copolymer film is then deposited on the carbon or fluoro-carbon neutral layer and crosslinked. Advantageously, the block copolymer comprises at least one silylated block. According to a non-essential but preferred embodiment of the invention, a top-coat can then be deposited on the BCP layer, so as to neutralize the upper interface of the BCP film, and crosslinked in whole or in part. Subsequently, the resulting stack of layers is heated to an assembly temperature in order to nanostructure said block copolymer. A subsequent step is then to remove at least one of the nano-domains from the nanostructured block copolymer film, in order to create a pattern intended to be transferred by etching into the thickness of the underlying substrate.

The first step of the method according to the invention therefore consists in depositing a neutral layer 20 directly on the surface of a substrate 10.

The substrate 10 can be solid, mineral, organic, or metallic in nature. Advantageously, but not exhaustively, the material constituting the substrate can be selected from: silicon or silicon oxide, aluminum oxide, titanium nitroxide, hafnium oxide, or a polymer material such as polymethylsiloxane PDMS, polycarbonate, or high-density polyethylene, or polyimide for example. In a particular example, the material constituting the substrate may include silicon or silica.

The neutral layer 20 is deposited directly on the substrate 10 and is itself covered by a silylated block copolymer. Thus, the conventional stack, comprising a substrate, an SOC layer, and an Si-ARC/SOG layer, on which the neutral layer and then the block copolymer layer are deposited, is not necessary. In other words, the neutral layer and the substrate are in contact.

The neutral layer 20 has a surface energy neutral with respect to each of the blocks of the block copolymer BCP to be deposited on its surface, that is to say it has no preferential affinity for any of the BCP blocks. This allows the domains of the block copolymer BCP to orient perpendicularly to the lower interface of the BCP layer in a subsequent step of nano-structuring the BCP.

In addition, the neutral layer 20 may comprise a fluorinated group, in order to adjust the surface energy of the layer for achieving neutrality with respect to each of the blocks of the block copolymer.

Advantageously, the neutral layer 20 according to the invention is an SOC (from the English acronym “Spin-on-Carbon”) carbon or fluoro-carbon type layer.

The carbon or fluoro-carbon neutral layer 20 (subsequently denoted n-SOC) advantageously has a chemical structure wholly or partly of the acrylate or methacrylate type based on co-monomers selected from (meth)acrylic monomers such as hydroxyalkyl acrylates such as 2-hydroxyethyl acrylate, glycidyl acrylates, dicyclopentenyloxyethyl acrylates, fluorinated methacrylates such as 2,2,2-trifluoroethyl methacrylate, tert-butyl acrylate or methacrylate, alone or as a mixture of at least two of the aforementioned comonomers.

The n-SOC layer may comprise at least three co-monomers of the glycidyl (meth)acrylate (denoted G) type, the hydroxyalkyl (meth)acrylate (denoted H) type, and the fluoroalkyl (meth)acrylate (denoted F) type, the proportion of each monomer G, H, F is between 10 and 90% by weight, with the sum of the 3 monomers being equal to 100%.

The n-SOC carbon or fluoro-carbon neutral layer is deposited to a thickness greater than 1.5 times the thickness of the block copolymer film subsequently deposited on its surface. Advantageously, the BCP to be deposited on the neutral layer comprises at least one silylated block.

The n-SOC layer 20 can be deposited by any techniques known in the field. Preferably the n-SOC layer is deposited on the substrate by spin-coating, for example from a solution of PGME-ethanol (propylene glycol methyl ether ethanol), or PGMEA (propylene glycol monomethyl ether acetate), or MIBK (methyl isobutyl ketone). To this end, the n-SOC layer preferably comprises hydroxy groups, promoting its solubility in polar solvents selected from at least one of the following solvents or solvent mixtures: MIBK, methanol, isopropanol, PGME, ethanol, PGMEA, ethyl lactate, cyclohexanone, cyclopentanone, anisole, alkyl acetate, n-butyl acetate, iso-amyl acetate, and promoting wetting of the copolymer film on the substrate. These hydroxy groups can for example be derived from a hydroxyalkyl (meth)acrylate co-monomer.

Once the n-SOC layer has been deposited on the substrate, it is crosslinked, in whole or in part. The crosslinked n-SOC layer 30 is a polymer material, the carbon matrix of which is hardened by crosslinking its chains. One of its objectives is to enable a rigid three-dimensional network to be obtained and to promote the mechanical strength of the layer. Crosslinking the neutral n-SOC layer prior to the deposition of the block copolymer also prevents the n-SOC layer from re-dissolving in the solvent of the block copolymer BCP during the deposition thereof.

Crosslinking is preferably carried out by exposure to thermalization, at a temperature between 0° C. and 450° C., preferably between 100° C. and 300° C., and more preferably between 200° C. and 250° C. for a period of less than or equal to 15 minutes, preferably less than or equal to 2 minutes.

Preferably, the n-SOC layer 20 comprises reactive groups of the epoxy type and/or unsaturations in its polymer chain, for example either directly in the body of the polymer chain itself, or as a pendant group therein, allowing its crosslinking by opening the reactive groups and/or unsaturations in order to create a dense three-dimensional network. Young's modulus is maximized by modulating the rate of reactive groups and/or unsaturations within the polymer chain. Indeed, the more reticulated the system, the less it will tend to move and collapse when important form factors are desired. To this end, the rate of reactive groups of the epoxy type and/or of unsaturations is preferably between 5% and 90%, preferably between 10% and 70%, and more preferably between 20% and 35% by weight relative to the total weight of the copolymer constituting the n-SOC layer.

The epoxy group(s) may be derived, for example, from a co-monomer of the glycidyl (meth)acrylate type.

In addition, at the time of this crosslinking step, the hydroxy groups of the n-SOC neutral layer participate in a grafting reaction of the n-SOC neutral layer 30 on the substrate 10. Indeed, at the time of crosslinking, the crosslinked n-SOC layer can be grafted on the substrate thanks to its hydroxy-OH groups, which then form covalent bonds with the substrate. The hydroxy-OH groups can be derived, for example, from a co-monomer of the hydroxyalkyl (meth)acrylate type.

This complementary grafting of the crosslinked n-SOC layer 30 on the substrate 10, thanks to the formation of covalent bonds with the substrate, advantageously avoids or delays any wetting phenomenon.

The neutral layer may optionally comprise a latent crosslinking agent selected from derivatives of the organic peroxide type, or derivatives having a chemical function of the azo type such as azobisisobutyronitrile, or derivatives of the alkyl halide type, or chemical derivatives for generating a thermally activated acid proton, such as ammonium salts such as ammonium triflate, ammonium trifluoroacetate, or ammonium trifluoromethane sulfonate, pyridinium salts such as pyridinium para-toluenesulfonate, phosphoric or sulfuric or sulfonic acids, or onium salts such as iodonium or phosphonium salts, or imidazolium salts. Such a crosslinking agent allows the crosslinking reaction to be catalyzed under specific operating conditions (temperature, radiation, mechanical stress, etc.) while guaranteeing the absence of reaction outside of said conditions, and thus the stability and/or lifetime of the non-crosslinked system.

Typically, with the latent crosslinking agent, the crosslinking reaction can be initiated at a temperature at least 20° C. lower than the crosslinking temperature of the copolymer constituting the n-SOC layer, taken alone, and preferably 30° C. lower, over a period of typically 15 minutes or less, and preferably 2 minutes or less.

Alternatively, crosslinking may be carried out by light irradiation, electrochemical process, plasma, ion bombardment, electron beam, mechanical stress, exposure to a chemical species, or any combination of the aforementioned techniques.

When crosslinking is carried out by light irradiation, the latent crosslinking agent could be a photo-generated acid (PAG) or a photo-generated base (PBG) for example, or a PAG assisted by a photoinitiator.

According to an alternative of the invention, a step of crosslinking the carbon or fluoro-carbon neutral layer 20 can consist in initiating a localized crosslinking, in order to define areas of interest of the n-SOC layer, by UV lithography, or electron beam for example, etc. Also, in this case, a latent crosslinking agent may be selected from a PAG or PBG sensitive to the wavelength selected to create a pattern by lithography.

In the context of light irradiation, it may be advisable to provide an anti-reflection agent/material under the n-SOC carbon or fluoro-carbon neutral layer, such as a Bottom Anti-Reflecting Coating (BARC) (from the English acronym “Bottom Anti-Reflecting Coating”) for example, or to provide for the incorporation of an anti-reflection agent into the material constituting the n-SOC carbon or fluoro-carbon layer, giving it anti-reflection properties. Indeed, it is preferable to prevent all light from bouncing off, in order not to create inhomogeneities in the layers. For example, the n-SOC layer may comprise an anti-reflective agent and/or material to prevent the n-SOC layer from reflecting light when irradiated with light. Advantageously, the anti-reflective agent absorbs incident radiation at a specific wavelength. Such an agent could for example be selected from sulfones, oligo-polystryrenes, compounds with an aromatic ring, or inorganic nanoparticles such as titanium oxides.

This anti-reflection property can also be obtained by depositing the n-SOC layer to a thickness greater than or equal to 1.5 times the thickness of the BCP layer, and judiciously selected to allow absorption of incident radiation at a given wavelength, in order to prevent all light from bouncing off. Thus, a carefully selected thickness of the n-SOC layer also provides anti-reflection properties.

A subsequent rinsing step allows non-crosslinked chains to be removed before the block copolymer film is deposited.

Rinsing is preferably carried out using a polar solvent or solvent mixture, selected from at least one of the following solvents: PGME-ethanol (propylene glycol methyl ether ethanol), PGMEA (propylene glycol methyl ether acetate), or MIBK (methyl isobutyl ketone), methanol, ethanol, isopropanol, ethyl lactate, cyclohexanone, anisole, alkyl acetate, n-butyl acetate, iso-amyl acetate.

Rinsing is preferably carried out using pure MIBK, or PGMEA.

After the n-SOC layer has been crosslinked 30, a film of block copolymer 40 is deposited on the surface of the crosslinked carbon or fluoro-carbon neutral layer. The block copolymer comprises at least one silylated block, so that it advantageously replaces the Si-ARC/SOG layer of a conventional stack dedicated to lithography.

Advantageously, the BCP layer 40 is deposited directly on the crosslinked carbon n-SOC neutral underlayer 30. Indeed, the n-SOC layer is directly neutral with respect to the BCP layer.

As regards the block copolymer BCP to be nanostructured, it comprises “n” blocks, with n being any integer greater than or equal to 2. The block copolymer BCP is more specifically defined by the following general formula:

A-b-B-b-C-b-D-b- . . . -fit-Z[Chem 1]

where A, B, C, D, . . . , Z are as many blocks “i” . . . “j” representing either pure chemical entities, that is to say each block is a set of monomers of identical chemical natures, polymerized together, or a set of comonomers, copolymerized together in the form, in whole or in part, of a block or statistical or random or gradient or alternating copolymer.

Each of the blocks “i” . . . “j” of the block copolymer BCP to be nanostructured can therefore potentially be written as: i=aᵢ-co-bᵢ-co- . . . -co-zᵢ, with i # . . . #j, in whole or in part.

The volume fraction of each entity aᵢ . . . zᵢ can range from 1 to 99%, by monomer units, in each of the blocks i . . . j of the block copolymer BCP.

The volume fraction of each of the blocks i . . . j may range from 5 to 95% of the block copolymer BCP.

The volume fraction is defined as the volume of an entity relative to that of a block, or the volume of a block relative to that of the block copolymer.

The volume fraction of each entity of a block of a copolymer, or of each block of a block copolymer, is measured as described below. Within a copolymer in which at least one of the entities, or one of the blocks if it is a block copolymer, includes several co-monomers, it is possible to measure, by proton NMR, the molar fraction of each monomer in the whole copolymer, and then to go back to the mass fraction using the molar mass of each monomer unit. To obtain the mass fractions of each entity of a block, or each block of a copolymer, it is then sufficient to add the mass fractions of the constituent co-monomers of the entity or block. The volume fraction of each entity or block can then be determined from the mass fraction of each entity or block and the density of the polymer forming the entity or block. However, it is not always possible to obtain the density of the polymers, the monomers of which are co-polymerized. In this case, the volume fraction of an entity or block is determined from its mass fraction and the density of the compound that represents the mass majority of the entity or block.

The molecular weight of the block copolymer BCP can range from 1000 to 500,000 g·mol⁻¹.

The block copolymer BCP can have any type of architecture: linear, star (three- or multi-arm), graft, dendritic, comb.

Each of the blocks i, j of a block copolymer has a surface energy denoted γᵢ . . . γⱼ, which is specific to it and which is a function of its chemical constituents, that is to say the chemical nature of the monomers or co-monomers constituting it. Similarly, the materials constituting a substrate each have their own surface energy value.

Each of the blocks I, . . . j of the block copolymer also has an interaction parameter of the Flory-Huggins type, denoted: χᵢₓ, when it interacts with a given material “x”, which can be a gas, a liquid, a solid surface, or another polymer phase for example, and an interfacial energy denoted “γᵢₓ”, with γᵢₓ=γᵢ−(γₓ cos θᵢₓ), where θᵢₓ is the non-zero contact angle between the materials i and x, with the material x forming a drop on material i. The interaction parameter between two blocks i and j of the block copolymer is thus denoted χᵢⱼ.

There is a relationship between γᵢ and the Hildebrand's solubility parameter δᵢ of a given material i, as described in document Jia et al., Journal of Macromolecular Science, B, 2011, 50, 1042. In fact, the Flory Huggins interaction parameter between two given materials i and x is indirectly related to the surface energies γi and γₓ specific to the materials, so one can either speak in terms of surface energies or in terms of interaction parameter to describe the physical phenomenon appearing at the interface of the materials.

When referring to the surface energies of a material and those of a given block copolymer BCP, it is implied that the surface energies are compared at a given temperature, and this temperature is the temperature (or at least part of the temperature range) at which the BCP can self-organize.

The block copolymer BCP, in solution in a polar solvent, is deposited by a conventional technique such as spin coating or “spin coating”. The block copolymer film has a thickness less than or equal to 1.5 times the thickness of the crosslinked underlying n-SOC neutral underlayer.

The BCP is deposited directly on the crosslinked n-SOC neutral layer 30.

The block copolymer is necessarily deposited in a liquid/viscous state so that it can nanostructure at the assembly temperature, in a subsequent annealing step.

Preferentially, but without limiting the invention, the block copolymer used is said to be “high-x” (has a high Flory-Huggins parameter), that is to say it must have a higher parameter than that of the so-called “PS-b-PMMA” system at the considered assembly temperature, such as defined by Y. Zhao, E. Sivaniah, and T. Hashimoto, Macromolecules, 2008, 41 (24), pages 9948-9951 (Determination of the Flory-Huggins parameter between styrene (“S”) and MMA (“M”): χSM=0.0282+(4.46/T)). Preferably, the BCP may have a XN product greater than or equal to 10.49.

Once the block copolymer has been deposited, the stack of layers thus created is subjected to thermal annealing, at an assembly temperature, for a period of less than or equal to 10 minutes, preferably less than or equal to 5 minutes, in order to nanostructure the block copolymer. The block copolymer self-assembles into nano-domains 41, 42 which then orient perpendicular to the neutralized lower interface of the block copolymer BCP.

In addition, the assembly annealing of the block copolymer at the assembly temperature advantageously allows grafting of the neutral underlayer 30 on the substrate 10 to be reinforced. When the BCP layer 40 is assembled and has the structured nanodomains 41, 42, a subsequent step is to remove at least one of the nanodomains 41, 42 from the block copolymer film, in order to create a pattern intended to be transferred by etching into the thickness of the underlying substrate. For example, as shown in FIG. 2, the nano-domains 42 are removed from the copolymer film.

One way of etching is to use dry etching such as plasma etching for example with appropriate gas chemistry. The chemistry of the plasma constituent gases can be adjusted depending on the materials to be removed.

Etching of the several layers can be carried out successively or simultaneously, in a same etching frame or in several etching frames, by plasma etching by adjusting the gas chemistry depending on the constituents of each of the layers to be removed. For example, the etching frame can be an inductively coupled reactor ICP (“Inductively Coupled Plasmas”) or a capacitively coupled reactor CCP (“Capacitively Coupled Plasmas”).

A first etching G1 consists in removing at least one nano-domain 42 from the block copolymer film. Depending on the nano-domain to be removed, the gas chemistry may be different. For example, in the case of the silylated block copolymer according to the invention, a plasma gas chemistry for the etching step may be based on O₂/N₂/HBr/Ar/CO/CO₂ alone or in combination to which a diluent gas such as He or Ar may be added. Preferably, but without limiting the invention, the gas chemistry or gas mixture of the step of removing one of the nano-domains must not significantly damage the underlying layers.

In addition, in a stack system comprising several layers, the etching resistance of each layer, for the creation of patterns, is a difficulty that must be overcome. For example, if the crosslinked n-SOC layer is etched too quickly, this can lead to poor control of the final dimensions of the patterns. Thus, a compromise must be found to control the etching speed of this layer. Advantageously, thanks to the fluorine groups of the n-SOC layer, derived from the fluoroalkyl(meth)acrylate type co-monomer, the crosslinked n-SOC layer is suitably resistant to etching G2 by plasma under oxygen. Thus, the crosslinked n-SOC layer is not etched too quickly under O₂, the fluorine groups allowing O₂ etching to be slowed down. This results in homogeneous patterns with an optimized form factor.

The etching G2 of the crosslinked n-SOC layer is preferably carried out by O₂-based plasma chemistry, for a period in the order of a few seconds to 1 minute.

Finally, the substrate, for example silicon, is plasma-etched G3 using halogen chemistry (SF₆, CH₃F, CH₂F₂, CHF₃, CF₄, HBr, Cl₂). The patterns are then transferred into the substrate which is etched to depths between 10 nm and 400 nm.

A final etch G4 (the so-called “stripping” step) consists in removing the residual layers of n-SOC and block copolymer BCP to keep only the etched substrate. This etching G4 can also be a dry etching and can take place in the same etching frame or in several etching frames with appropriate gas chemistry.

This method is applied in DSA to obtain interesting and optimized form factors.

In addition, it is no longer necessary to use a large number of intermediate layers such as Si-ARC/SOG, SOC, and neutral layer.

Thus, the method according to the invention allows the number of steps and resources to be minimized while allowing a substrate to be deeply etched, to a thickness typically greater than or equal to 15 nm with a large form factor greater than or equal to 1.

Alternatively, prior to the nano-structuring step of the block copolymer BCP, the method may comprise a step of depositing a third top-coat (named TC) type layer on the upper surface of the block copolymer. This third layer, which is neutral with respect to each of the blocks of the block copolymer, is then crosslinked and/or subjected to a post-exposure bake (PEB), in whole or in part, by subjecting it, in whole or in part, to an annealing at a temperature lower than the assembly temperature of the block copolymer, before the step of nano-structuring the block copolymer. This annealing can be a so-called “post-apply” bake, denoted PAB (from the English acronym “Post Apply Bake”) and carried out right after a polymer layer has been deposited in order to evaporate the residual solvent from the corresponding film, and/or a so-called “post-exposure” bake or PEB (from the English acronym “Post-Exposure bake”) and carried out right after exposure of the layer comprising a sensitive material (for example a photosensitive or electrosensitive material) in order to propagate, in said layer of the sensitive material, the diffusion of the acids/bases released during exposure. Typically, crosslinking and/or PEB of the top coat layer is carried out at a temperature of around 90° C. for a period of around 3 minutes. This layer may optionally comprise a thermal latent crosslinking agent, for example of the ammonium triflate type, of the PAG type such as onium, sulfonium, iodonium salts, such as triphenylsulfonium triflate. The block copolymer is then nanostructured at its assembly temperature, and then the top coat TC layer is completely removed by plasma etching with gas chemistry of the Ar/O₂ type before removing one of the nano-domains from the block copolymer. Such a top coat TC layer deposited on the top surface of the block copolymer is advantageously neutral with respect to each of the blocks of the block copolymer, and ensures that the nano-domains of the block copolymer are oriented perfectly perpendicular to the two lower and upper interfaces at the time of the nano-structuring step of the block copolymer.

A pattern can be drawn in the top-coat layer and/or the underlayer either directly by a standard lithography step, such as exposure to light radiation of a specific wavelength or a localized electron beam for example; or by depositing an additional layer of standard lithography resin on the top-coat layer after it has cured, and then creating the pattern in said resin layer by standard lithography. In both cases, it will be necessary to ensure that the corresponding material stack (at least the underlayer and BCP) has anti-reflection properties for the wavelength selected in the case of an optical lithography step. Where necessary, a BARO (from the English acronym “Bottom Anti-Reflecting Coating) bottom anti-reflecting coating may be dispensed for this purpose prior to stacking the layers of following materials.

### Exemplary Embodiment

According to an illustrative but not limiting example of the present invention, the block copolymer BCP used is of the PDMSB-b-PS (poly(dimethylsilacyclobutane)-block-polystyrene) type. In the particular case presented here, a top-coat is used. In addition, for reasons of simplification, the TC and n-SOC have the same chemical structure, and the proportion of co-monomers may vary. However, this is not mandatory. Indeed, it is possible to use chemically non-equivalent copolymers.

In this illustrative example, the n-SOC layer is a layer of poly(glycidyl methacrylate-co-hydroxyethyl methacrylate-co-trifluoroethyl methacrylate) (abbreviated to PGFH thereafter) copolymer.

The n-SOC layer comprises epoxy groups at a minimum rate of 20 to 25% by weight based on the total weight of the copolymer constituting the n-SOC layer.

An n-SOC/latent agent mixture in solution in PGME-ethanol, or PGMEA, or MI BK is dispensed by spin-coating, to a thickness of the order of 60 nm, on a silicon substrate. An exemplary thermal latent crosslinking agent is ammonium triflate, introduced at less than 30% of the final n-SOC solid mass, preferably less than 11% of the final n-SOC solid mass.

The n-SOC layer thus deposited is crosslinked at 240° C. for 2 minutes, and then rinsed by simple spin-coating of pure MIBK. The block copolymer BCP, in solution in 1% MIBK by weight, is dispensed by spin-coating to a thickness of about 30 nm on the crosslinked n-SOC layer.

In this example, a top coat material in solution in absolute ethanol, with its latent crosslinking agent, such as ammonium triflate for example, is dispensed to a thickness of the order of 60 nm on the BCP layer. The top-coat is crosslinked at 90° C. for 3 minutes.

The BCP layer is then nanostructured at 240° C. for 5 minutes.

The top-coat is then removed by plasma etching with Ar/O₂ gas chemistry so that the BCP film can be imaged by scanning electron microscopy.

The results are shown in FIG. 3.

FIG. 3A shows a top view scanning electron microscope photograph of the BCP assembly. For the analysis of the sectioned sample, via FIB-STEM (fast ion bombardment-scanning transmission electronic microscope) preparation, the following procedure is used: the preparation of the thin slide of the sample as well as its STEM analysis are carried out on a Helios 450S apparatus. A 100 nm platinum layer is first deposited on the sample by evaporation to prevent polymer damage. An additional 1 μm layer is deposited on the sample in the STEM enclosure by a high-energy ion beam. After careful alignment perpendicularly to the sample (sectional view), a thin slide thereof is extracted via FIB, and then gradually refined until a width of approximately 100 nm is obtained. An in-situ observation is then carried out using STEM. The result of the analysis is shown in FIG. 3B, which is a sectional view, by FIB-STEM preparation, of the TC/BCP/n-SOC stack, the lamellar block copolymer of which is self-assembled. Microscopy indicates that the BCP lamellae are perpendicular to the n-SOC layer and the Si substrate, over the entire thickness of the film (in dark gray: PDMSB lamellae; in light gray: PS lamellae).

FIG. 3C shows a cross-sectional scanning electron microscope photograph of a BCP/n-SOC stack after removal of the PS phase from the BCP.

These photographs demonstrate that it is possible to obtain a block copolymer, the nano-domains of which are oriented perpendicular to the interfaces, on a thick and crosslinked carbon layer, deposited directly on the surface of a substrate.

1. A directed self-assembly lithography method, said method comprising a step of depositing a block copolymer film on a layer neutral with respect to each block of the block copolymer, said block copolymer film being for use as a lithography mask, said lithography method comprising the following steps of:
depositing said neutral layer directly on a surface of a substrate, said neutral layer being of a carbon or fluoro-carbon type (n-SOC) deposited to a thickness greater than 1.5 times a thickness of said block copolymer film,
crosslinking all or part of said carbon or fluoro-carbon neutral layer,
depositing said block copolymer film on said crosslinked carbon or fluoro-carbon neutral layer, said block copolymer comprising at least one silylated block,
subjecting the stack of layers thus created to an assembly temperature in order to nanostructure said block copolymer,
removing at least one nano-domain from said nanostructured block copolymer, in order to create a pattern intended to be transferred by etching into the carbon or fluoro-carbon neutral layer, and then into a thickness of the underlying substrate.

2. The lithography method according to claim 1, wherein the carbon or fluoro-carbon neutral layer comprises reactive groups of an epoxy type and/or unsaturations in its polymer chain either directly in a body of the polymer chain itself, or as a pendant group therein.

3. The lithography method according to claim 2, wherein a minimum rate of reactive groups of the epoxy type and/or of unsaturations in the polymer chain of the carbon or fluoro-carbon neutral layer is 10% and 70%.

4. The lithography method according to claim 1, wherein the carbon or fluoro-carbon neutral layer further comprises a latent crosslinking agent selected from derivatives of an organic peroxide type, or derivatives having a chemical function of an azo type, or derivatives of an alkyl halide type, or chemical derivatives for generating a thermally activated acid proton selected from among: ammonium salts, pyridinium salts, phosphoric or sulfuric or sulfonic acids, onium salts, imidazolium salts, photo-generated acids and photo-generated bases.

5. The lithography method according to claim 1, wherein the carbon or fluoro-carbon neutral layer has, in whole or in part, a chemical structure of an acrylate or methacrylate type based on comonomers selected from among: hydroxyalkyl acrylates, glycidyl acrylates, dicyclopentenyloxyethyl acrylates, fluorinated methacrylates, tert-butyl acrylates, methacrylates, and mixtures of at least two of the aforementioned comonomers.

6. The lithography method according to claim 1, wherein the carbon or fluoro-carbon neutral layer comprises hydroxy groups promoting its solubility in polar solvents selected from at least one of the following solvents or solvent mixtures: MIBK, methanol, isopropanol, PGME, ethanol, PGMEA, ethyl lactate, cyclohexanone, cyclopentanone, anisole, alkyl acetate, n-butyl acetate, iso-amyl acetate.

7. The lithography method according to claim 1, wherein the carbon or fluoro-carbon neutral layer comprises at least three co-monomers of a glycidyl (meth)acrylate type (G), a hydroxyalkyl (meth)acrylate (H) type, and a fluoroalkyl (meth)acrylate (F) type, and wherein a proportion of each said monomer G, H, F is between 10 and 90% by weight, with a sum of the 3 monomers being equal to 100%.

8. The lithography method according to claim 1, further comprising a step of depositing a third layer on a surface of the block copolymer, such that prior to the step of nano-structuring the block copolymer film, said third layer is crosslinked in whole or in part.

9. The lithography method according to the claim 8, wherein the third layer comprises a latent crosslinking agent selected from: a chemical derivatives for generating a thermally activated acid proton selected from among: ammonium salts, onium salts, sulfonium salts, phosphonium or imidazolium salts, a photo-generated acid (PAG), and a photo-generated base (PBG).

10. The lithography method according to claim 1, wherein the step of crosslinking the carbon or fluoro-carbon neutral layer (n-SOC) and/or the third layer is carried out by light irradiation, exposure to self-thermalization, electrochemical process, plasma, ion bombardment, electron beam, mechanical stress, exposure to a chemical species, or any combination of the aforementioned techniques.

11. The lithography method according to claim 10, wherein the step of crosslinking the carbon or fluoro-carbon neutral layer is carried out by exposure to thermalization, at a temperature between 100 and 300° C. for a period of less than or equal to 15 minutes.

12. The lithography method according to claim 1, wherein a pattern can be drawn in the neutral layer by exposure to light radiation or an electron beam.

13. The lithography method according to one of claim 8, wherein a pattern can be drawn in the third layer, by exposure to light radiation or an electron beam.

14. The lithography method according to claim 12, wherein when the pattern is drawn by exposure to light radiation, at least the carbon or fluoro-carbon neutral and the block copolymer have anti-reflection properties.

15. The lithography method according to claim 12, wherein when the pattern is drawn by exposure to light radiation, a bottom anti-reflection coating is dispensed on the substrate, prior to the deposition of said carbon or fluoro-carbon neutral layer.

16. The lithography method according to claim 1, wherein the step of depositing the neutral layer directly on the surface of the subtract comprises a direct contact between said neutral layer and the substrate.

17. The lithography method according to claim 1, wherein the step of depositing the block copolymer film on the crosslinked carbon or fluoro-carbon neutral layer comprises a direct contact between said crosslinked carbon or fluoro-carbon neutral layer and the block copolymer film.

18. The lithography method according to claim 1, wherein said lithography method excludes use of intermediate layer such as Si-ARC/SOG, SOC, and neutral layer.

19. Lithography stack obtained by a directed self-assembly lithography method, said stack comprising a substrate to a surface of which is deposited a neutral layer, said neutral layer being covered by a block copolymer film, said block copolymer film being for use as a lithography mask, and said neutral layer being neutral with respect to each of block of the block copolymer, wherein the neutral layer is in direct contact with the underlying substrate, the neutral layer being of a carbon or fluoro-carbon type (n-SOC), crosslinked in whole or in part, deposited to a thickness greater than 1.5 times a thickness of said block copolymer film, said block copolymer film comprising at least one silylated block, and being in direct contact with said crosslinked carbon or fluoro-carbon neutral layer, said block copolymer film having been nanostructured by treatment at an assembly temperature and being a discontinuous film, in order to create a pattern capable of being transferred by etching in the carbon or fluoro-carbon neutral layer then in the thickness of the underlying substrate.

20. Method according to claim 1, wherein a lithography mask intended to allow the etching of patterns at depths between 10 nm and 400 nm is thereby manufactured.
